(19) United States
(12) Patent Application Publication
(10) Pub. No.: US 2025/0107102 A1
(43) Pub. Date: Mar. 27, 2025

(54) SEMICONDUCTOR DEVICE

(71) Applicant: Samsung Electronics Co., Ltd., Suwon-si (KR)

(72) Inventors: Junhoe KIM, Suwon-si (KR); Kilho LEE, Suwon-si (KR); Shin KWON, Suwon-si (KR); Hyeonah JO, Suwon-si (KR)

(73) Assignee: Samsung Electronics Co., Ltd., Suwon-si (KR)

(21) Appl. No.: 18/620,469

(22) Filed: Mar. 28, 2024

(30) Foreign Application Priority Data
Sep. 27, 2023 (KR) 10-2023-0130259

(51) Int. Cl. H10B 61/00; G01R 33/09; H10N 50/10

(52) U.S. Cl. CPC H10B 61/22; G01R 33/098; H10N 50/10

(57) ABSTRACT

A semiconductor device includes a substrate including a cell region and a peripheral region, a first lower insulating layer disposed on the cell region and extending onto the peripheral region, a second lower insulating layer disposed on the first lower insulating layer on the cell region and extending onto the first lower insulating layer on the peripheral region, data storage patterns disposed on the second lower insulating layer on the cell region, a cell insulating layer disposed on the second lower insulating layer on the cell region and covering the data storage patterns, and a peripheral insulating layer disposed on the second lower insulating layer on the peripheral region and including a material different from the cell insulating layer. A thickness of the second lower insulating layer on the peripheral region is smaller than a maximum thickness of the second lower insulating layer on the cell region.

### CROSS-REFERENCE TO RELATED APPLICATIONS

This U.S. non-provisional patent application claims priority under 35 U.S.C. § 119 to Korean Patent Application No. 10-2023-0130259, filed on Sep. 27, 2023, in the Korean Intellectual Property Office, the entire contents of which are hereby incorporated by reference.

### BACKGROUND

Various example embodiments relate to a semiconductor device and/or a method of manufacturing the same, and more specifically, relate to a semiconductor device including a magnetic tunnel junction and/or a method of manufacturing the same.

With the high speed and/or low power consumption of electronic devices, there is an increasing requirement or expectations for high speed and/or low operating voltage of semiconductor devices incorporated in an electronic device. To meet or at least partially meet these expectations, magnetic memory devices have been proposed as semiconductor memory devices. Because magnetic memory devices may exhibit characteristics such as high-speed operation and/or non-volatility, they are being spotlighted as the next-generation semiconductor devices.

In general, a magnetic memory device may include a magnetic tunnel junction (MTJ) pattern. The MTJ pattern may include two magnetic substances and an insulating layer interposed therebetween. Resistance of the MTJ pattern may vary depending on magnetization directions of the two magnetic substances. For example, when the magnetization directions of the two magnetic substances are antiparallel to each other, the MTJ pattern may have low resistance. Data may be written/read using the resistance difference.

With various needs or desires of the electronics industry, various studies have been conducted on semiconductor devices having an embedded structure in which magnetic tunnel junction patterns are disposed between metal wirings.

### SUMMARY

Some example embodiments may provide a semiconductor device capable of reducing or minimizing defects resulting from a manufacturing process, and/or a method of manufacturing the same.

Alternatively or additionally, some example embodiments may provide a semiconductor device with improved electrical characteristics and/or a method of manufacturing the same.

A semiconductor device according to some example embodiments may include a substrate including a cell region and a peripheral region, a first lower insulating layer on the cell region and extending onto the peripheral region, a second lower insulating layer on the cell region and on the first lower insulating layer and extending onto the first lower insulating layer on the peripheral region, data storage patterns on the cell region and on the second lower insulating layer, a cell insulating layer on the cell region and on the second lower insulating layer and covering the data storage patterns, and a peripheral insulating layer on the peripheral region and on the second lower insulating layer and including a material different from materials in the cell insulating layer. A thickness of the second lower insulating layer on the peripheral region may be smaller than a maximum thickness of the second lower insulating layer on the cell region.

Alternatively or additionally a semiconductor device according to some example embodiments may include a substrate including a cell region and a peripheral region, a first lower insulating layer on the cell region and extending onto the peripheral region, a second lower insulating layer on the cell region and on the first lower insulating layer and extending onto the first lower insulating layer on the peripheral region, data storage patterns on the cell region and on the second lower insulating layer, lower electrode contacts on the cell region, penetrating the first lower insulating layer and the second lower insulating layer, and connected to the data storage patterns, respectively, a cell insulating layer on the cell region and on the second lower insulating layer and covering the data storage patterns, a peripheral insulating layer on the second lower insulating layer on the peripheral region and including a material different from materials of the cell insulating layer, and a peripheral conductive contact in the peripheral insulating layer and penetrating the first lower insulating layer and the second lower insulating layer on the peripheral region. An upper surface of the second lower insulating layer on the peripheral region may be positioned at a lower height than an uppermost surface of the second lower insulating layer on the cell region. The peripheral insulating layer may be in contact with a side surface of the cell insulating layer and the upper surface of the second lower insulating layer on the peripheral region.

### BRIEF DESCRIPTION OF THE DRAWINGS

Various example embodiments will be more clearly understood from the following brief description taken in conjunction with the accompanying drawings. The accompanying drawings represent non-limiting, example embodiments as described herein.

FIG. 1 is a circuit diagram showing a unit memory cell of a semiconductor device according to some example embodiments.

FIG. 2 is a plan view of a semiconductor device according to some example embodiments.

FIG. 3 is a cross-sectional view taken along line I-I′ of FIG. 2.

FIGS. 4A and 4B are cross-sectional views showing examples of magnetic tunnel junction patterns of semiconductor devices according to some example embodiments, respectively.

FIG. 5 is an enlarged view of portion ‘A’ of FIG. 3.

FIGS. 6 to 11 are views illustrating a method of manufacturing a semiconductor device according to some example embodiments, and are cross-sectional views corresponding to line I-I′ of FIG. 2.

FIG. 12 is an enlarged view of portion ‘B’ of FIG. 11

### DETAILED DESCRIPTION

Hereinafter, inventive concepts will be described in detail by explaining various example embodiments with reference to the accompanying drawings.

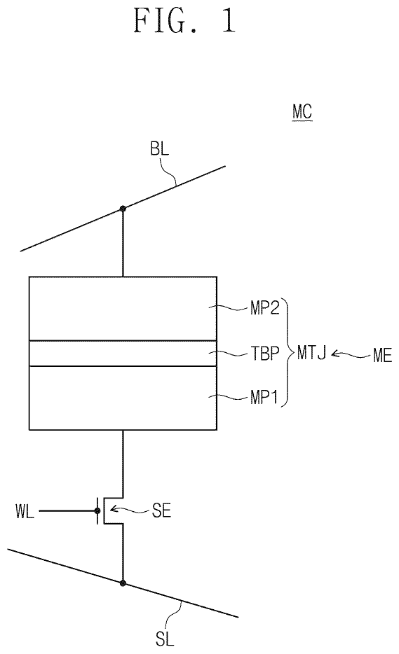

FIG. 1 is a circuit diagram showing a unit memory cell of a semiconductor device according to some example embodiments.

Referring to FIG. 1, a unit memory cell MC may include a memory element ME and a selection element SE. The memory element ME and the selection element SE may be electrically connected to each other in series. The memory element ME may be connected between a column line or a bit line BL and the selection element SE. The selection element SE may be connected between the memory element ME and a source line SL and may be controlled by a row line or a word line WL. In some example embodiments, the source line SL and the bit line BL may be orthogonal to each other; however, example embodiments are not limited thereto. The selection element SE may be or may include, for example, a bipolar transistor and/or a MOS field effect transistor. In some example embodiments, the selection element SE may be an NMOS transistor; however, example embodiments are not limited thereto.

The memory element ME may be or may include a magnetic tunnel junction pattern MTJ including magnetic patterns MP1 and MP2 spaced apart from each other and a tunnel barrier pattern TBP between the magnetic patterns MP1 and MP2. One of the magnetic patterns MP1 and MP2 may be or may correspond to a reference magnetic pattern having a magnetization direction pinned in one direction regardless of an external magnetic field under a normal use environment. The other of the magnetic patterns MP1 and MP2 may be or may correspond to a free magnetic pattern in which a magnetization direction is changed between two stable magnetization directions by an external magnetic field. An electrical resistance of the magnetic tunnel junction pattern MTJ may be much higher, e.g., several orders of magnitude higher, when magnetization directions of the reference magnetic pattern and the free magnetic pattern are antiparallel to each other than when magnetization directions are parallel to each other. For example, the electrical resistance of the magnetic tunnel junction pattern MTJ may be adjusted by changing the magnetization direction of the free magnetic pattern. Accordingly, the memory element ME may store data in the unit memory cell MC using a difference in electrical resistance depending on magnetization directions of the reference magnetic pattern and the free magnetic pattern.

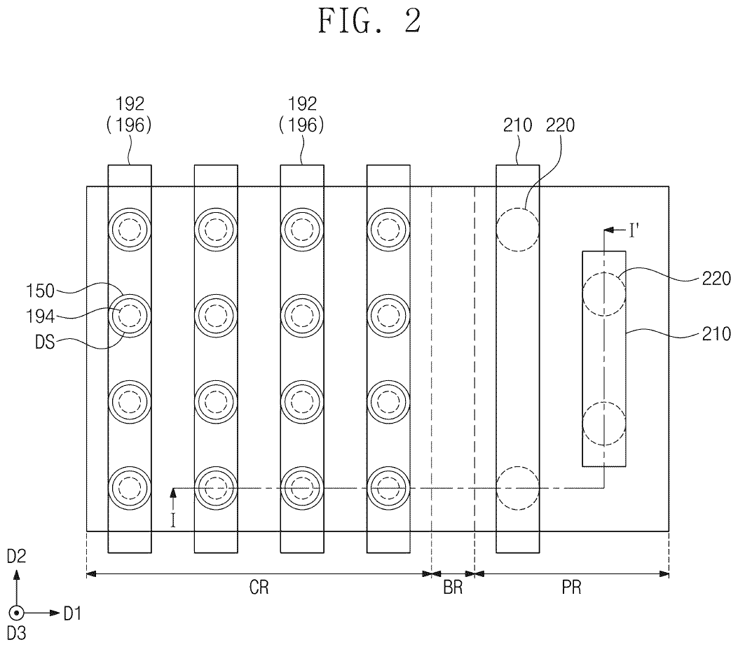

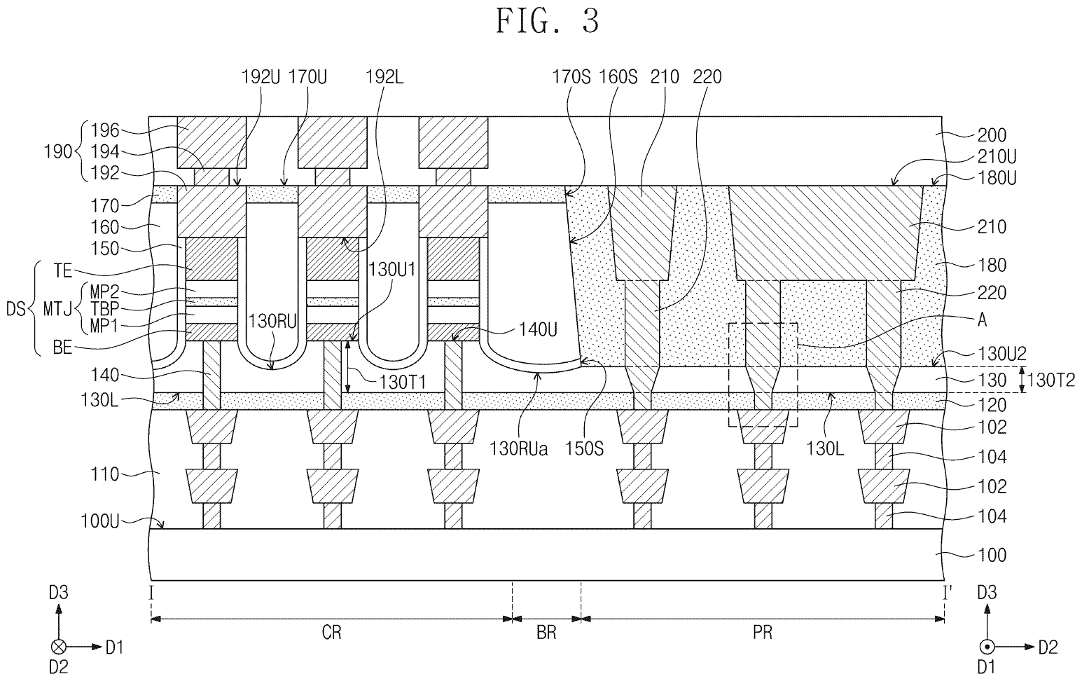

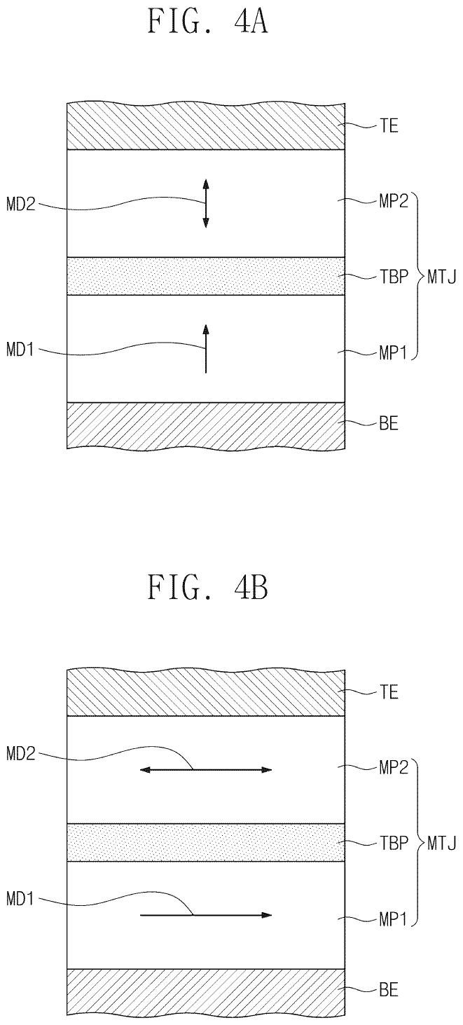

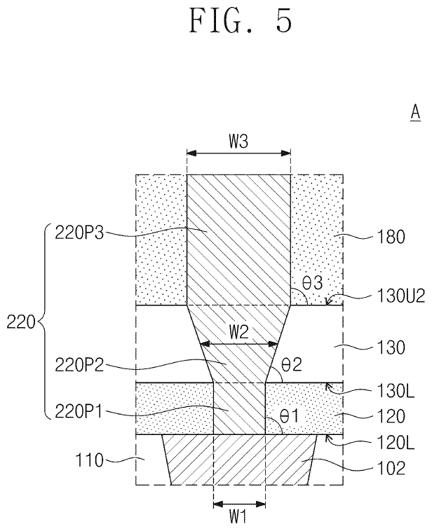

FIG. 2 is a plan view of a semiconductor device according to some example embodiments. FIG. 3 is a cross-sectional view taken along line I-I′ of FIG. 2. FIGS. 4A and 4B are cross-sectional views showing examples of magnetic tunnel junction patterns of semiconductor devices according to some example embodiments, respectively. FIG. 5 is an enlarged view of portion ‘A’ of FIG. 3.

Referring to FIGS. 2 and 3, a substrate 100 may be provided including a cell region CR, a peripheral region PR, and a boundary region BR therebetween. The substrate 100 may be or may include a semiconductor substrate containing or composed of one or more of silicon (Si), silicon on insulator (SOI), silicon germanium (SiGe), germanium (Ge), gallium arsenide (GaAs), etc. The cell region CR may be or may correspond to a region of the substrate 100 where the memory cells MC of FIG. 1 are provided, and the peripheral region PR may be or may correspond to another region of the substrate 100 where peripheral circuits for driving and/or reading the memory cells MC are provided. The boundary region BR may be the other region of the substrate 100 provided between the cell region CR and the peripheral region PR.

Wiring structures 102 and 104 may be disposed on the substrate 100. The wiring structures 102 and 104 may be disposed on the cell region CR and the peripheral region PR of the substrate 100. The wiring structures 102 and 104 may include wiring lines 102 vertically spaced from the substrate 100 and wiring contacts 104 connected to the wiring lines 102. The wiring lines 102 may be spaced apart from an upper surface 100U of the substrate 100 in a direction perpendicular to the upper surface 100U of the substrate 100. The wiring contacts 104 may be disposed between the substrate 100 and the wiring lines 102. Each of the wiring lines 102 may be electrically connected to the substrate 100 through a corresponding one of the wiring contacts 104. The wiring lines 102 and the wiring contacts 104 may include metal (e.g., copper). Although two levels are illustrated for the wiring structures 102 and 104, example embodiments are not limited thereto. In some examples, the wiring structures 102 and 104 may have different line widths and/or different pitches from one another; example embodiments are not limited thereto.

Selection elements SE (of FIG. 1) may be disposed on the cell region CR of the substrate 100, and peripheral transistors constituting (or included in) the peripheral circuits may be disposed on the peripheral region PR of the substrate 100. For example, the selection elements and the peripheral transistors may be or may include field effect transistors such as NMOS and/or PMOS field effect transistors. Each of the wiring lines 102 may be electrically connected to one (or more) terminal (e.g., a source terminal, a drain terminal, or a gate terminal) of a corresponding one of the selection elements, or one (or more) terminals (e.g., a source terminal, a drain terminal, or a gate terminal) of a corresponding one of the peripheral transistors, through a corresponding one of the wiring contacts 104.

A wiring insulating layer 110 may be disposed on the substrate 100 to cover the wiring structures 102 and 104. The wiring insulating layer 110 may be disposed on the cell region CR of the substrate 100 and may extend onto the boundary region BR and the peripheral region PR of the substrate 100. The wiring insulating layer 110 may expose upper surfaces of the uppermost wiring lines 102 among the wiring lines 102. For example, an upper surface of the wiring insulating layer 110 may be substantially coplanar with the upper surfaces of the uppermost wiring lines 102. For example, the wiring insulating layer 110 may include at least one of silicon oxide, silicon nitride, and/or silicon oxynitride.

A first lower insulating layer 120 may be disposed on the wiring insulating layer 110 and may cover the exposed upper surfaces of the uppermost wiring lines 102. The first lower insulating layer 120 may be disposed on the wiring insulating layer 110 on the cell region CR, and may extend onto the wiring insulating layer 110 on the boundary region BR and the peripheral region PR. For example, the first lower insulating layer 120 may include one or more of silicon oxide, silicon nitride, and/or silicon oxynitride, and may include the same or different materials than that of the wiring insulating layer 110.

A second lower insulating layer 130 may be disposed on the first lower insulating layer 120. The second lower insulating layer 130 may be disposed on the first lower insulating layer 120 on the cell region CR, and may extend onto the first lower insulating layer 120 on the boundary region BR and the peripheral region PR. The first lower insulating layer 120 may be interposed between the wiring insulating layer 110 and the second lower insulating layer 130 on the cell region CR, the boundary region BR, and the peripheral region PR. For example, the second lower insulating layer 130 may include one or more of silicon oxide, silicon nitride, and/or silicon oxynitride.

The second lower insulating layer 130 may include a material different from that of or any of the first lower insulating layer 120. In some example embodiments, the second lower insulating layer 130 and the first lower insulating layer 120 may not include any common material. As an example, the first lower insulating layer 120 may include silicon nitride (e.g., SiCN), and the second lower insulating layer 130 may include silicon oxide (e.g., tetrathoxysilane (TEOS)). In some examples, the first lower insulating layer 120 may not include silicon oxide, and/or the second lower insulating layer 130 may not include silicon nitride.

Data storage patterns DS may be disposed on the second lower insulating layer 130 on the cell region CR. The data storage patterns DS may be spaced apart from each other in a first direction D1 and a second direction D2 that are parallel to the upper surface 100U of the substrate 100 and intersect each other.

The second lower insulating layer 130 on the cell region CR may have a recessed upper surface 130RU that is recessed toward the substrate 100 between the data storage patterns DS. The recessed upper surface 130U of the second lower insulating layer 130 on the cell region CR may be positioned at a lower height than an uppermost surface 130U1 of the second lower insulating layer 130 on the cell region CR. As described herein, a height is a distance measured from the upper surface 100U of the substrate 100 in the third direction D3 perpendicular to the upper surface 100U of the substrate 100.

An upper surface 130U2 of the second lower insulating layer 130 on the peripheral region PR may be positioned at a lower height than the uppermost surface 130U1 of the second lower insulating layer 130 on the cell region CR. According to some example embodiments, the upper surface 130U2 of the second lower insulating layer 130 on the peripheral region PR may be positioned at a lower height than the recessed upper surface 130RU of the second lower insulating layer 130 on the cell region CR. Alternatively according to some example embodiments, the upper surface 130U2 of the second lower insulating layer 130 on the peripheral region PR may be positioned at the same height as the recessed upper surface 130RU of the second lower insulating layer 130 on the cell region CR. Alternatively according to some example embodiments, the upper surface 130U2 of the second lower insulating layer 130 on the peripheral region PR may be positioned at a height higher than the recessed upper surface 130RU of the second lower insulating layer 130 on the cell region CR.

The second lower insulating layer 130 on the boundary region BR may have a recessed upper surface 130RUa that is recessed toward the substrate 100. The recessed upper surface 130RUa of the second lower insulating layer 130 on the boundary region BR may be positioned at a lower height than the uppermost surface 130U1 of the second lower insulating layer 130 on the cell region CR. According to some example embodiments, the recessed upper surface 130RUa of the second lower insulating layer 130 on the boundary region BR may be positioned at a lower height than the recessed upper surface 130RU of the second lower insulating layer 130 on the cell region CR, and may be positioned at a lower height than the upper surface 130U2 of the second lower insulating layer 130 on the peripheral region PR.

A thickness 130T2 of the second lower insulating layer 130 on the peripheral region PR may be smaller than a maximum thickness 130T1 of the second lower insulating layer 130 on the cell region CR (e.g., 130T1>130T2). The thickness 130T2 of the second lower insulating layer 130 on the peripheral region PR may be measured in the third direction D3 from a lower surface 130L of the second lower insulating layer 130 to the upper surface 130U2 of the second lower insulating layer 130 on the peripheral region PR. The maximum thickness 130T1 of the second lower insulating layer 130 on the cell region CR may be measured in the third direction D3 from the lower surface 130L of the second lower insulating layer 130 to the uppermost surface 130U1 of the second lower insulating layer 130 on the cell region CR. For example, the thickness 130T2 of the second lower insulating layer 130 on the peripheral region PR may be in the range of 30 Å to 350 Å (3 nm to 35 nm), and preferably, may be in the range of 50 Å to 250 Å (5 nm to 25 nm).

Lower electrode contacts 140 may be disposed in the second lower insulating layer 130 on the cell region CR and may be spaced apart from each other in the first direction D1 and the second direction D2. The lower electrode contacts 140 may be respectively disposed below the data storage patterns DS and may be electrically connected to the data storage patterns DS, respectively. Each of the lower electrode contacts 140 may penetrate the first and second lower insulating layers 120 and 130 on the cell region CR, and may be connected to a corresponding one of the uppermost wiring lines 102. Each of the data storage patterns DS may be electrically connected to one terminal or at least one terminal (e.g., a drain terminal) of the corresponding selection element through each of the lower electrode contacts 140 and the corresponding uppermost wiring line 102.

Upper surfaces 140U of the lower electrode contacts 140 may be positioned at a higher height than the recessed upper surface 130RU of the second lower insulating layer 130 on the cell region CR. The upper surfaces 140U of the lower electrode contacts 140 may be positioned at the same height as the uppermost surface 130U1 of the second lower insulating layer 130 on the cell region CR. The recessed upper surface 130RUa of the second lower insulating layer 130 on the boundary region BR and the upper surface 130U2 of the second lower insulating layer 130 on the peripheral region PR may be positioned at a lower height than the upper surfaces 140U of the lower electrode contacts 140.

The lower electrode contacts 140 may include at least one of a doped semiconductor material (e.g., doped silicon), a metal (e.g., tungsten, titanium, and/or tantalum), a metal-semiconductor compound (e.g., metal silicide), and a conductive metal nitride (e.g., titanium nitride, tantalum nitride, and/or tungsten nitride).

Each of the data storage patterns DS may include a lower electrode BE, a magnetic tunnel junction pattern MTJ, and an upper electrode TE sequentially stacked on the second lower insulating layer 130 in the third direction D3. The magnetic tunnel junction pattern MTJ may be disposed between the lower electrode BE and the upper electrode TE. Each of the lower electrode contacts 140 may be connected to the lower electrode BE of each of the data storage patterns DS. The lower electrode BE of each of the data storage patterns DS may be in contact with the upper surface 140U of each of the lower electrode contacts 140 and the uppermost surface 130U1 of the second lower insulating layer 130 on the cell region CR.

The magnetic tunnel junction pattern MTJ may include a first magnetic pattern MP1, a second magnetic pattern MP2, and a tunnel barrier pattern TBP therebetween. The first magnetic pattern MP1 may be disposed between the lower electrode BE and the tunnel barrier pattern TBP, and the second magnetic pattern MP2 may be disposed between the upper electrode TE and the tunnel barrier pattern TBP. For example, the lower electrode BE may include a conductive metal nitride (e.g., titanium nitride and/or tantalum nitride). The upper electrode TE may include at least one of a metal (e.g., one or more of Ta, W, Ru, Ir, etc.) and a conductive metal nitride (e.g., TiN and/or TaN).

Referring to FIGS. 4A and 4B, in some example embodiments the first magnetic pattern MP1 may be or correspond to a reference layer having a magnetization direction MD1 pinned in one direction, and the second magnetic pattern MP2 may be or correspond to a free layer having a magnetization direction MD2 changeable to be parallel or anti-parallel to the magnetization direction MD1 of the first magnetic pattern MP1. Referring to FIGS. 4A and 4B each show a case in which the second magnetic pattern MP2 is a free layer as an example, but the concept of the present disclosure is not limited thereto. Unlike FIGS. 4A and 4B, alternatively or additionally the first magnetic pattern MP1 may be or correspond to a free layer and the second magnetic pattern MP2 may be or correspond to a reference layer.

Referring to FIG. 4A, the magnetization directions MD1 and MD2 of the first magnetic pattern MP1 and the second magnetic pattern MP2 may be perpendicular to an interface the tunnel barrier pattern TBP and the second magnetic pattern MP2. In this case, each of the first magnetic pattern MP1 and the second magnetic pattern MP2 may include at least one of an intrinsic perpendicular magnetic substance and an extrinsic perpendicular magnetic substance. The intrinsic perpendicular magnetic substance may include a material having perpendicular magnetization characteristics even when there is no external factor, e.g., no external electric or magnetic field. The intrinsic perpendicular magnetic substance may include at least one of i) perpendicular magnetic substance (e.g., CoFeTb, CoFeGd, CoFeDy), ii) perpendicular magnetic substance having an L1₀ structure, iii) CoPt having a hexagonal close packed lattice structure, and iv) vertical magnetic structures. The perpendicular magnetic substance having the L1₀ structure may include at least one of FePt of L1₀ structure, FePd of L1₀ structure, CoPd of L1₀ structure, or CoPt of L1₀ structure. The perpendicular magnetic structure may include magnetic layers and non-magnetic layers that are alternately and repeatedly stacked. For example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n (“n” is the number of stacking). The extrinsic perpendicular magnetic substance may include a material having intrinsic horizontal magnetization characteristics and perpendicular magnetization characteristics due to an external factor. For example, the extrinsic perpendicular magnetic substance may have the perpendicular magnetization characteristics due to magnetic anisotropy induced by making a junction of the first magnetic pattern MP1 (or the second magnetic pattern MP2) and the tunnel barrier pattern TBP. The extrinsic perpendicular magnetic substance may include, for example, CoFeB.

Referring to FIG. 4B, as another example, the magnetization directions MD1 and MD2 of the first magnetic pattern MP1 and the second magnetic pattern MP2 may be parallel to the interface the tunnel barrier pattern TBP and the second magnetic pattern MP2. In this case, each of the first magnetic pattern MP1 and the second magnetic pattern MP2 may include a ferromagnetic substance. The first magnetic pattern MP1 may further include an antiferromagnetic substance for pinning a magnetization direction of the ferromagnetic substance in the first magnetic pattern MP1.

Each of the first magnetic pattern MP1 and the second magnetic pattern MP2 may include a cobalt-based Heusler alloy. The tunnel barrier pattern TBP may include at least one of a magnesium (Mg) oxide layer, a titanium (Ti) oxide layer, an aluminum (Al) oxide layer, a magnesium-zinc (Mg—Zn) oxide layer, or a magnesium-boron (Mg—B) oxide layer.

Referring again to FIGS. 2 and 3, a capping insulating layer 150 may be disposed on the second lower insulating layer 130 on the cell region CR. The capping insulating layer 150 may conformally cover a side surface of each of the data storage patterns DS and the recessed upper surface 130RU of the second lower insulating layer 130 on the cell region CR. The capping insulating layer 150 may surround the side surface of each of the data storage patterns DS when viewed in a plan view. The capping insulating layer 150 may extend onto the second lower insulating layer 130 on the boundary region BR, and may conformally cover the recessed upper surface 130RUa of the second lower insulating layer 130 on the boundary region BR.

The capping insulating layer 150 may conformally cover side surfaces of the lower electrode BE, the magnetic tunnel junction pattern MTJ, and the upper electrode TE. The capping insulating layer 150 may surround the side surfaces of the lower electrode BE, the magnetic tunnel junction pattern MTJ, and the upper electrode TE when viewed in a plan view. The capping insulating layer 150 may include nitride (e.g., silicon nitride). The capping insulating layer 150 may have a planar upper surface; however, example embodiments are not limited thereto.

A cell insulating layer 160 may be disposed on the second lower insulating layer 130 on the cell region CR and may cover the data storage patterns DS. The cell insulating layer 160 may fill a space between the data storage patterns DS. The capping insulating layer 150 may be interposed between the side surface of each of the data storage patterns DS and the cell insulating layer 160, and may extend between the recessed upper surface 130RU of the second lower insulating layer 130 on the cell region CR and the cell insulating layer 160. The cell insulating layer 160 may extend onto the second lower insulating layer 130 on the boundary region BR. The capping insulating layer 150 may extend between the cell insulating layer 160 and the recessed upper surface 130RUa of the second lower insulating layer 130 on the boundary region BR. For example, the cell insulating layer 160 may include at least one of silicon oxide, silicon nitride, and/or silicon oxynitride.

An upper insulating layer 170 may be disposed on the cell insulating layer 160 on the cell region CR. The upper insulating layer 170 may extend onto the cell insulating layer 160 on the boundary region BR. The upper insulating layer 170 may include a material different from the cell insulating layer 160. As an example, the cell insulating layer 160 may include silicon oxide, and the upper insulating layer 170 may include silicon nitride (e.g., SiCN and/or SiN). The cell insulating layer 160 may include the same or different material than the capping insulating layer 150, and may or may not have the same thickness as the capping insulating layer 150.

A peripheral insulating layer 180 may be disposed on the second lower insulating layer 130 on the peripheral region PR. The peripheral insulating layer 180 may be in contact with the upper surface 130U2 of the second lower insulating layer 130 on the peripheral region PR. The peripheral insulating layer 180 may be in contact with a side surface 160S of the cell insulating layer 160 and a side surface 170S of the upper insulating layer 170. The peripheral insulating layer 180 may be in contact with a side surface 150S of the capping insulating layer 150.

An upper surface 180U of the peripheral insulating layer 180 may be positioned at the same height as an upper surface 170U of the upper insulating layer 170. The upper surface 180U of the peripheral insulating layer 180 may be coplanar with the upper surface 170U of the upper insulating layer 170.

The peripheral insulating layer 180 may include a material different from the cell insulating layer 160. The peripheral insulating layer 180 may include an insulating material with a lower dielectric constant (k) than that of the cell insulating layer 160. The peripheral insulating layer 180 may include a material different from the upper insulating layer 170, and may include an insulating material with a dielectric constant (k) smaller than that of the upper insulating layer 170. The peripheral insulating layer 180 may include a material different from that of or any of the materials of the second lower insulating layer 130. For example, there may not be a common material between the peripheral insulating layer 180 and the second lower insulating layer 130 For example, the peripheral insulating layer 180 may include silicon oxide, silicon nitride, and/or silicon oxynitride. As an example, the peripheral insulating layer 180 may include an insulating material with a dielectric constant (k) of about 2.5 or less than 2.0, for example, porous SiOC.

First cell conductive lines 192 may be disposed on the cell region CR. The first cell conductive lines 192 may be spaced apart from each other in the first direction D1 and may extend in the second direction D2. Each of the first cell conductive lines 192 may have a line shape extending in the second direction D2. Each of the first cell conductive lines 192 may be electrically connected to corresponding data storage patterns spaced apart from each other in the second direction D2, among the data storage patterns DS, respectively. The data storage patterns DS spaced apart from each other in the first direction D1 among the data storage patterns DS may be electrically connected to the first cell conductive lines 192, respectively.

Each of the first cell conductive lines 192 may penetrate the upper insulating layer 170 and may penetrate an upper portion of the cell insulating layer 160 to be connected to the corresponding data storage pattern DS. A lower surface 192L of each of the first cell conductive lines 192 may be in contact with the upper electrode TE of the corresponding data storage pattern DS. An upper surfaces 192U of the first cell conductive lines 192 may be positioned at the same height as the upper surface 170U of the upper insulating layer 170, and may be coplanar with the upper surface 170U of the upper insulating layer 170. The first cell conductive lines 192 may include a conductive material, for example, metal (for example, copper).

Peripheral conductive lines 210 may be disposed on the second lower insulating layer 130 on the peripheral region PR and in the peripheral insulating layer 180. The peripheral insulating layer 180 may cover the peripheral conductive lines 210. An upper surface 210U of the peripheral conductive lines 210 may be exposed without being covered by the peripheral insulating layer 180. The upper surfaces 210U of the peripheral conductive lines 210 may be positioned at the same height as the upper surface 180U of the peripheral insulating layer 180 and may be coplanar with the upper surface 180U of the peripheral insulating layer 180. The upper surfaces 210U of the peripheral conductive lines 210, the upper surfaces 180U of the peripheral insulating layer 180, the upper surfaces 192U of the first cell conductive lines 192, and the upper surfaces 170U of the upper insulating layer 170 may be positioned at the same height and may be coplanar with each other.

Peripheral conductive contacts 220 may be disposed on the peripheral region PR and below the peripheral conductive lines 210. The peripheral conductive contacts 220 may be electrically connected to the peripheral conductive lines 210. Each of the peripheral conductive contacts 220 may be in contact with a corresponding peripheral conductive line 210 among the peripheral conductive lines 210 without an interface therebetween; for example, each of the peripheral conductive contacts 220 may be formed or filled at the same time as (e.g., with a damascene process as) the peripheral conductive lines 210. Each of the peripheral conductive contacts 220 and the corresponding peripheral conductive line 210 may be connected to each other to form an integrated unit. Each of the peripheral conductive contacts 220 may penetrate a lower portion of the peripheral insulating layer 180. Each of the peripheral conductive contacts 220 may penetrate the second lower insulating layer 130 and the first lower insulating layer 120 on the peripheral region PR, and may be electrically connected to a corresponding one of the uppermost wiring lines 102. Each of the peripheral conductive lines 210 may be electrically connected to one (or at least one) terminal (e.g., a source terminal, a drain terminal, or a gate terminal) of a corresponding peripheral transistor, through corresponding peripheral conductive contacts 220 and corresponding uppermost wiring lines 102.

Referring to FIG. 5, each of the peripheral conductive contacts 220 may include a first portion 220P1 in the first lower insulating layer 120, a second portion 220P2 in the second lower insulating layer 130, and a third portion 220P3 in the peripheral insulating layer 180. Each of the peripheral conductive contacts 220 may have a width in a direction parallel to the upper surface 100U of the substrate 100. A first width W1 of the first portion 220P1 may be smaller than a third width W3 of the third portion 220P3, and a second width W2 of the second portion 220P2 may decrease as the second portion 220P2 is farther from the third portion 220P3 in a direction perpendicular to the upper surface 100U of the substrate 100 and as the second portion 220P2 is closer to the first portion 220P1. A side surface of the first portion 220P1 may be linear or curved, and may be inclined at a first angle θ1 with respect to the lower surface 120L of the first lower insulating layer 120, and a side surface of the second portion 220P2 may be linear or curved, and may be inclined at a second angle θ2 with respect to the lower surface 130L of the second lower insulating layer 130. The second angle θ2 may be different from the first angle θ1. A side surface of the third portion 220P3 may be linear or curved, and may be inclined at a third angle θ3 with respect to the upper surface 130U2 of the second lower insulating layer 130 on the peripheral region PR. The second angle θ2 may be different from the third angle θ3. As an example, each of the first angle θ1 and the third angle θ3 may be less than or equal to 90°, and the second angle θ2 may be smaller than the first angle θ1 and the third angle θ3.

Referring again to FIGS. 2 and 3, the peripheral conductive lines 210 and the peripheral conductive contacts 220 may include a conductive material, for example, metal (e.g., copper). The first cell conductive lines 192, the peripheral conductive lines 210, and the peripheral conductive contacts 220 may include the same material. In some example embodiments, each of the first conductive lines 192, the peripheral conductive lines 210, and the peripheral conductive contacts 220 may be formed at the same time, e.g., with a damascene process; example embodiments are not limited thereto.

The upper interlayer insulating layer 200 may be disposed on the cell region CR, the boundary region BR, and may cover the upper surface 170U of the upper insulating layer 170, the upper surfaces 192U of the first cell conductive lines 192, the upper surface 180U of the peripheral insulating layer 180, and the upper surfaces 210U of the peripheral conductive lines 210. For example, the upper interlayer insulating layer 200 may include at least one of silicon oxide, silicon nitride, and/or silicon oxynitride.

Second cell conductive lines 196 may be disposed in the upper interlayer insulating layer 200 on the cell region CR. The second cell conductive lines 196 may be spaced apart from each other in the first direction D1 and may extend in the second direction D2. The second cell conductive lines 196 may overlap each of the first cell conductive lines 192 vertically (e.g., in the third direction D3). Conductive contacts 194 may be disposed in the upper interlayer insulating layer 200 on the cell region CR and may be disposed between the first cell conductive lines 192 and the second cell conductive lines 196. Each of the first cell conductive lines 192 may be electrically connected to each of the second cell conductive lines 196 through corresponding conductive contacts 194 of the conductive contacts 194. Each of the first cell conductive lines 192, the corresponding conductive contacts 194, and each of the second cell conductive lines 196 may constitute or be included in a bit line 190 (bit line BL of FIG. 1). The conductive contacts 194 and the second cell conductive lines 196 may include a conductive material, for example, metal (for example, copper).

According to various example embodiments, on the peripheral region PR, the second lower insulating layer 130 may be interposed between the first lower insulating layer 120 and the peripheral insulating layer 180. In this case, the first lower insulating layer 120 may be prevented from or may be reduced in likelihood of and/or impact from being recessed during the etching process performed before forming the peripheral insulating layer 180, and as a result, the upper surface of the uppermost wiring lines 102 may be prevented or reduced from being recessed.

The upper surface 130U2 of the second lower insulating layer 130 on the peripheral region PR may be positioned at a lower height than the uppermost surface 130U1 of the second lower insulating layer 130 on the cell region CR, and the thickness 130T2 of the second lower insulating layer 130 on the peripheral region PR may be smaller than the maximum thickness 130T1 of the second lower insulating layer 130 on the cell region CR. The thickness 130T2 of the second lower insulating layer 130 on the peripheral region PR may be in the range of 30 Å to 350 Å. When the thickness 130T2 of the second lower insulating layer 130 on the peripheral region PR is less than 30 Å, it may be difficult to prevent or improve upon recesses in the first lower insulating layer 120 and the upper wiring lines during the etching process. When the thickness 130T2 of the second lower insulating layer 130 on the peripheral region PR is greater than 350 Å (35 nm), parasitic capacitance between the peripheral conductive contacts 220 and/or between the peripheral conductive lines 210 may increase, and accordingly, electrical characteristics of the semiconductor device may deteriorate.

Alternatively or additionally, each of the peripheral conductive contacts 220 may include the first portion 220P1 in the first lower insulating layer 120, the second portion 220P2 in the second lower insulating layer 130, and the third portion 220P3 in the peripheral insulating layer 180. The second lower insulating layer 130 may include a material different from the first lower insulating layer 120 and the peripheral insulating layer 180, and accordingly, each of the peripheral conductive contacts 220 may be formed to have the width W2 that decreased as the second portion 220P2 is farther away from the third portion 220P3 and closer to the first portion 220P1. As a result, the width W1 of the first portion 220P1 may be smaller than the width W3 of the third portion 220P3. When the thickness 130T2 of the second lower insulating layer 130 on the peripheral region PR is greater than 350 Å (35 nm), the width W1 of the first portion 220P1 may decrease, and as a result, resistance of each of the peripheral conductive contacts 220 may be increased. Accordingly, electrical characteristics of the semiconductor device may deteriorate.

Accordingly, on the peripheral region PR, the second lower insulating layer 130 may be interposed between the first lower insulating layer 120 and the peripheral insulating layer 180 and may have the required thickness 130T2, thereby providing the semiconductor device capable of minimizing or reducing process-related defects and/or having improved electrical characteristics.

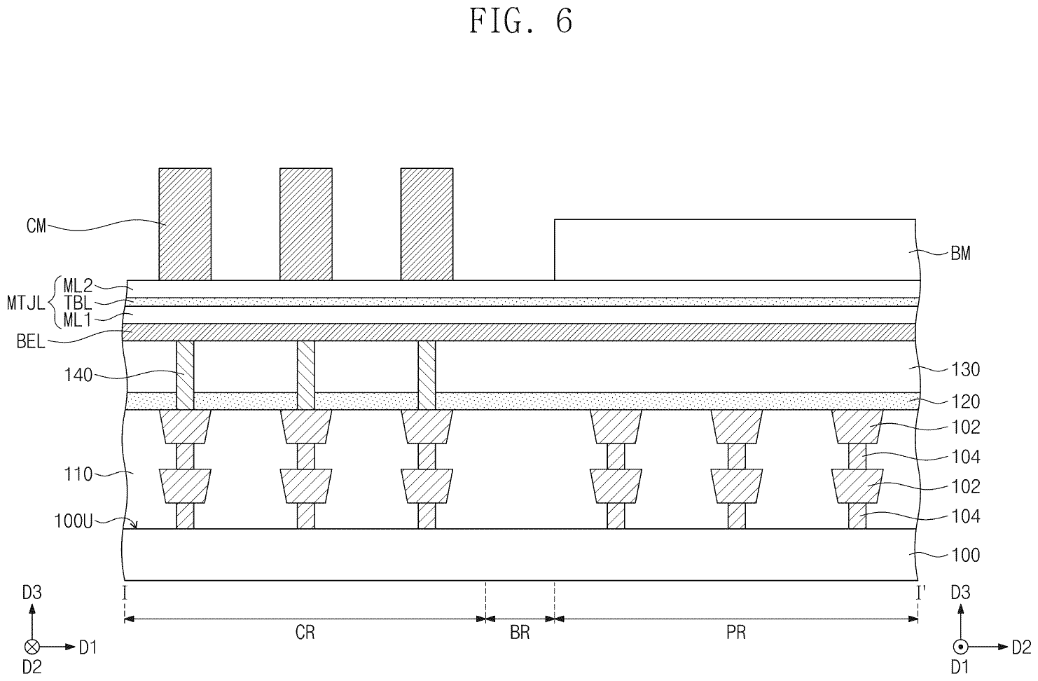

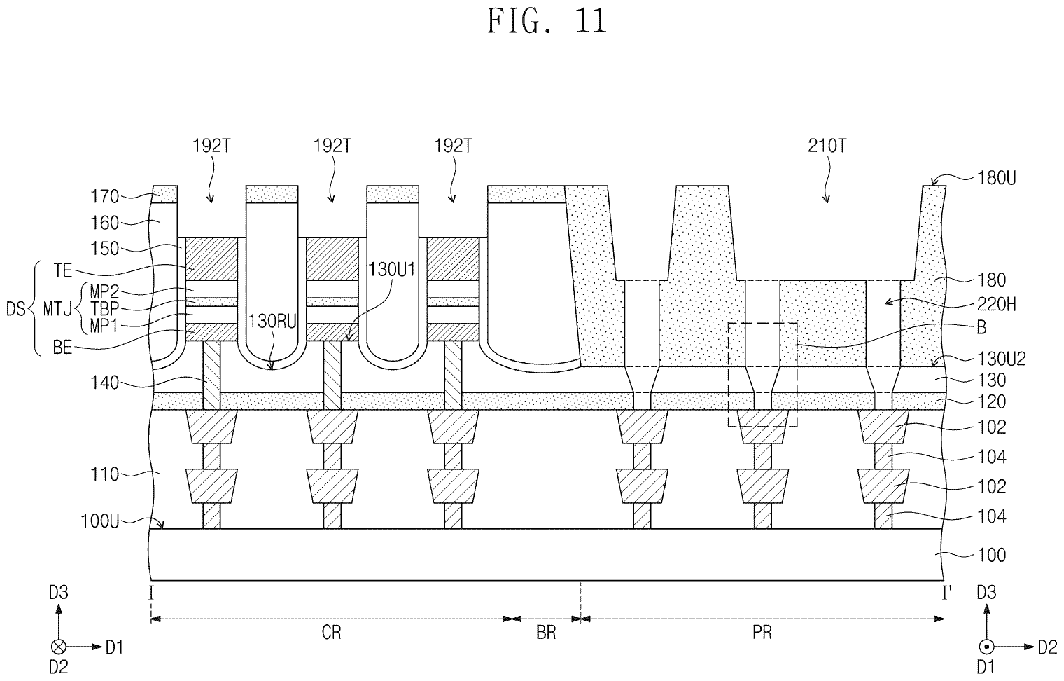

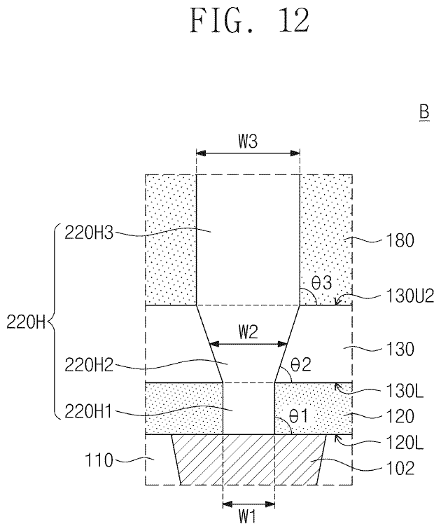

FIGS. 6 to 11 are views illustrating a method of manufacturing a semiconductor device according to some example embodiments, and are cross-sectional views corresponding to line I-I′ of FIG. 2. FIG. 12 is an enlarged view of portion ‘B’ of FIG. 11. For simplicity of explanation, descriptions that overlap with the semiconductor device described with reference to FIGS. 1 to 3, 4A, 4B, and 5 are omitted.

Referring to FIGS. 2 and 6, a substrate 100 including a cell region CR, a peripheral region PR, and a boundary region BR therebetween may be provided. Selection elements SE (in FIG. 1) and peripheral transistors (not shown) may be formed on the substrate 100, and wiring structures 102 and 104 may include wiring lines 102 spaced vertically (e.g., in the third direction D3) from the substrate 100, and wiring contacts 104 connected to the wiring lines 102. Each of the wiring lines 102 may be electrically connect to one or more than one terminal (e.g., source terminal, drain terminal, or gate terminal) of a corresponding one of the selection elements or to one or more than one terminal (e.g., source terminal, drain terminal, or gate terminal) of a corresponding one of the peripheral transistors, through a corresponding one of the wiring contacts 104.

A wiring insulating layer 110 may be formed on the substrate 100 and cover the wiring structures 102 and 104. The wiring insulating layer 110 may expose upper surfaces of the uppermost wiring lines 102 among the wiring lines 102. The wiring insulating layer 110 may be formed with a process such as one or more of a plasma enhanced chemical vapor deposition (PECVD) process, a low pressure CVD (LPCVD) process, or an atomic layer deposition (ALD) process; example embodiments are not limited thereto. In some cases, the wiring insulating layer 110 may be planarized, e.g., with a chemical mechanical planarization (CMP) process and/or an etch back process; example embodiments are not limited thereto.

A first lower insulating layer 120 may be formed on the wiring insulating layer 110 and may cover the exposed upper surfaces of the uppermost wiring lines 102. The first lower insulating layer 120 may be formed on the wiring insulating layer 110 on the cell region CR, and may extend onto the wiring insulating layer 110 on the boundary region BR and the peripheral region PR. The first lower insulating layer 120 may be formed with one or more of a PECVD process, an LPCVD process, or an ALD process; example embodiments are not limited thereto. In some cases, the first lower insulating layer 120 may be planarized, e.g., with a CMP process and/or an etch back process; example embodiments are not limited thereto.

A second lower insulating layer 130 may be formed on the first lower insulating layer 120. The second lower insulating layer 130 may be formed on the first lower insulating layer 120 on the cell region CR, may extend onto the first lower insulating layer on the boundary region BR and the peripheral region PR. The second lower insulating layer 130 may be formed with one or more of a PECVD process, an LPCVD process, or an ALD process; example embodiments are not limited thereto. In some cases, the second lower insulating layer 130 may be planarized, e.g., with a CMP process and/or an etch back process; example embodiments are not limited thereto

Lower electrode contacts 140 may be formed in the second lower insulating layer 130 on the cell region CR. Each of the lower electrode contacts 140 may penetrate the first and second lower insulating layers 120 and 130 on the cell region CR, and may be electrically connected to one of the uppermost wiring lines 102. Forming the lower electrode contacts 140 may include, for example, forming lower contact holes penetrating the first and second lower insulating layers 120 and 130 on the cell region CR, forming a lower contact layer on the second lower layer 30 to fill the lower contact holes, and planarizing the lower contact layer until an upper surface of the second lower insulating layer 130 is exposed. Through the planarization process, the lower electrode contacts 140 may be formed locally in the lower contact holes, respectively. The planarization process may include a CMP process and/or an etch-back process.

A lower electrode layer BEL and a magnetic tunnel junction layer MTJL may be sequentially deposited on the second lower insulating layer 130. The lower electrode layer BEL and the magnetic tunnel junction layer MTJL may be formed on the second lower insulating layer 130 on the cell region CR, and may extend onto the second loser insulating layer 130 on the boundary region BR and the peripheral region. The magnetic tunnel junction layer MTJL may include a first magnetic layer ML1, a tunnel barrier layer TBL, and a second magnetic layer ML2 sequentially stacked on the lower electrode layer BEL. For example, the magnetic tunnel junction layer MTJL and the lower electrode layer BEL may be formed through one or more of a sputtering process such as a physical vapor deposition process, a CVD process, or an ALD process.

Conductive mask patterns CM may be formed on the magnetic tunnel junction layer MTJL on the cell region CR. The conductive mask patterns CM may define a region where magnetic tunnel junction patterns MTJ, which will be described later, will be formed. The conductive mask patterns CM may be spaced apart from each other in the first direction D1 and the second direction D2 on the magnetic tunnel junction layer MTJL, and may be formed of metal (e.g., one or more of Ta, W, Ru, Ir, etc.) and a conductive metal nitride (e.g., TiN).

A blocking mask pattern BM may be formed on the magnetic tunnel junction layer MTJL on the peripheral region PR. The blocking mask pattern BM may cover the magnetic tunnel junction layer MTJL on the peripheral region PR and expose the magnetic tunnel junction layer MTJL on the boundary region BR. For example, the blocking mask pattern BM may include silicon nitride and/or metal nitride. The blocking mask pattern BM may be formed before, after, or concurrently with the conductive mask patterns CM.

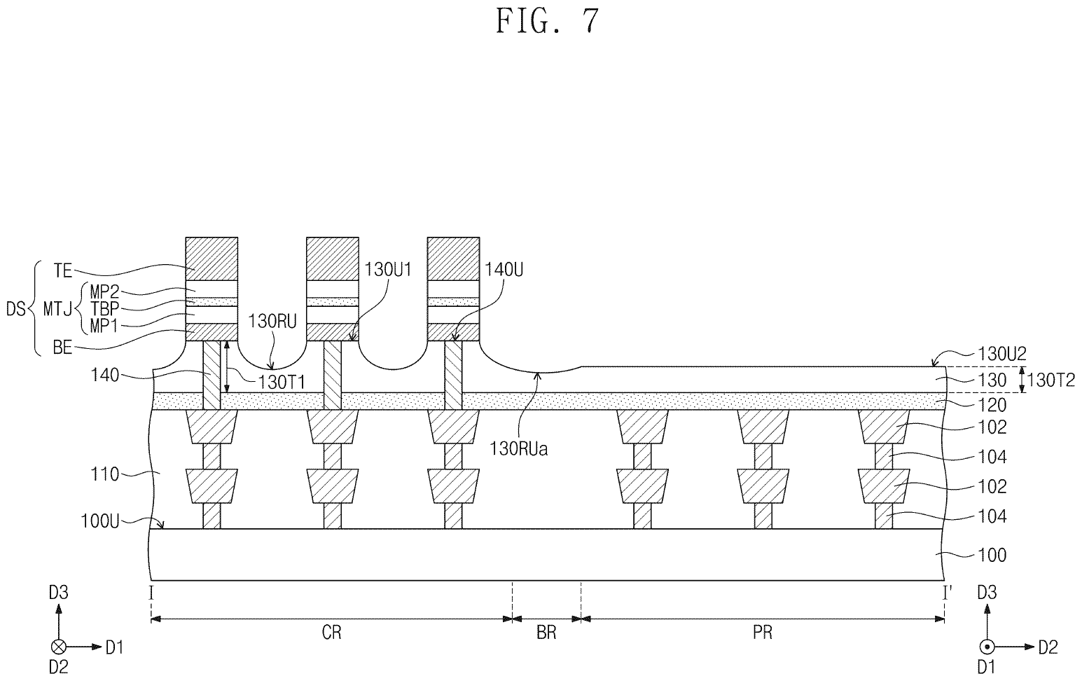

Referring to FIGS. 2 and 7, a first etching process may be performed to etch the magnetic tunnel junction layer MTJL and the lower electrode layer BEL using the conductive mask patterns CM as an etch mask. For example, the first etching process may be or may include an ion beam etching process using an ion beam. The ion beam may include inert ions such as but not limited to noble gas ions. As the magnetic tunnel junction layer MTJL and the lower electrode layer BEL are etched, a magnetic tunnel junction pattern MTJ and a lower electrode BE may be formed, respectively.

Etching the magnetic tunnel junction layer MTJL may include sequentially etching the second magnetic layer ML2, the tunnel barrier layer TBL, and the first magnetic layer ML1. The second magnetic layer ML2, the tunnel barrier layer TBL, and the first magnetic layer ML1 may be etched to form a second magnetic pattern MP2, a tunnel barrier pattern TBP, and a first magnetic pattern MP1, respectively. The remainder of the conductive mask pattern CM remaining on the magnetic tunnel junction pattern MTJ after the first etching process may be referred to as an upper electrode TE. The lower electrode BE, the magnetic tunnel junction pattern MTJ, and the upper electrode TE may be referred to as a data storage pattern DS. A plurality of data storage patterns DS may be formed on each of the lower electrode contacts 140 and may be spaced apart from each other in the first direction D1 and the second direction D2.

By the first etching process, an upper portion of the second lower insulating layer 130 between the plurality of data storage patterns DS may be recessed. Accordingly, the second lower insulating layer 130 on the cell region CR may have a recessed upper surface 130RU that is recessed toward the substrate 100. The recessed upper surface 130RU of the second lower insulating layer 130 on the cell region CR may be positioned at a lower height than the upper surfaces 140U of the lower electrode contacts 140, and may be positioned at a lower height than an uppermost surface 130U1 of the second lower insulating layer 130 on the cell region CR.

The blocking mask pattern BM may be removed during the first etching process, and the magnetic tunnel junction layer MTJL and the lower electrode layer BEL on the boundary region BR and the peripheral region PR may also be removed during the first etching process. In addition, an upper portion of the second lower insulating layer 130 on the boundary region BR and the peripheral region PR may be recessed by the first etching process.

An upper surface 130U2 of the second lower insulating layer 130 on the peripheral region PR may be positioned at a lower height than the uppermost surface 130U1 of the second lower insulating layer 130 on the cell region CR. As a thickness of the blocking mask pattern BM (e.g., a thickness in the third direction D3) is adjusted, the upper surface 130U2 of the second lower insulating layer 130 on the peripheral region PR may be controlled to be positioned at a higher height or at a lower height than the recessed upper surface 130RU of the second lower insulating layer 130 on the cell region CR, and may be controlled to be positioned at the same height as the recessed upper surface 130RU of the second lower insulating layer 130 on the cell region CR.

A thickness 130T2 of the second lower insulating layer 130 on the peripheral region PR may be smaller than a maximum thickness 130T1 of the second lower insulating layer 130 on the cell region CR (e.g., 130T1>130T2). As the thickness of the blocking mask pattern BM (e.g., the thickness on the third direction D3) is adjusted, the thickness 130T2 of the second lower insulating layer 130 on the peripheral region PR may be controlled to be in a range of 30 Å (3 nm) to 350 Å (35 nm).

The recessed upper surface 130RUa of the second lower insulating layer 130 on the boundary region BR may be positioned at a lower height than the uppermost surface 130U1 of the second lower insulating layer 130 on the cell region CR. The blocking mask pattern BM may not be provided on the boundary region BR, and accordingly, the recessed upper surface 130RUa of the second lower insulating layer 130 on the boundary region BR may be positioned at a lower height than the recessed upper surface 130RU of the second lower insulating layer 130 on the cell region CR and the upper surface 130U2 of the second lower insulating layer 130 on the peripheral region PR.

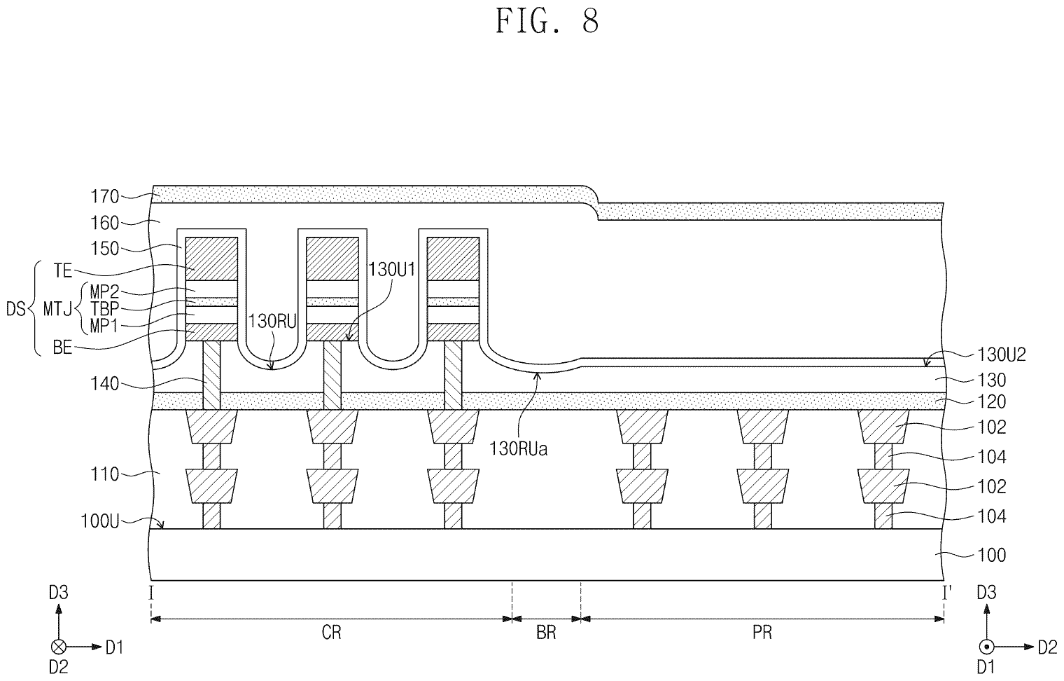

Referring to FIGS. 2 and 8, a capping insulating layer 150 may be formed on the second lower insulating layer 130 on the cell region CR, and may conformally cover an upper surface and a side surface of each of the data storage patterns DS. The capping insulating layer 150 may conformally cover the recessed upper surface 130RU of the second lower insulating layer 130 on the cell region CR. The capping insulating layer 150 may extend onto the second lower insulating layer 130 on the boundary region BR, and may conformally cover the recessed upper surface 130RUa of the second lower insulating layer 130 on the boundary region BR. The capping insulating layer 150 may extend onto the second lower insulating layer 130 on the peripheral region PR, and may cover the upper surface 130U2 of the second lower insulating layer 130 on the peripheral region PR.

A cell insulating layer 160 may be formed on the capping insulating layer 150. The cell insulating layer 160 may be formed on the capping insulating layer 150 on the cell region CR to cover the data storage patterns DS and fill a space between the data storage patterns DS. The cell insulating layer 160 may extend onto the capping insulating layer 150 on the boundary region BR and the peripheral region PR. For example, the cell insulating layer 160 may be formed using a high density plasma chemical vapor deposition (HDP CVD) process.

An upper insulating layer 170 may be formed on the cell insulating layer 160. The upper insulating layer 170 may be formed on the cell insulating layer 160 on the cell region CR, and may extend onto the cell insulating layer 160 on the boundary region BR and the peripheral region PR.

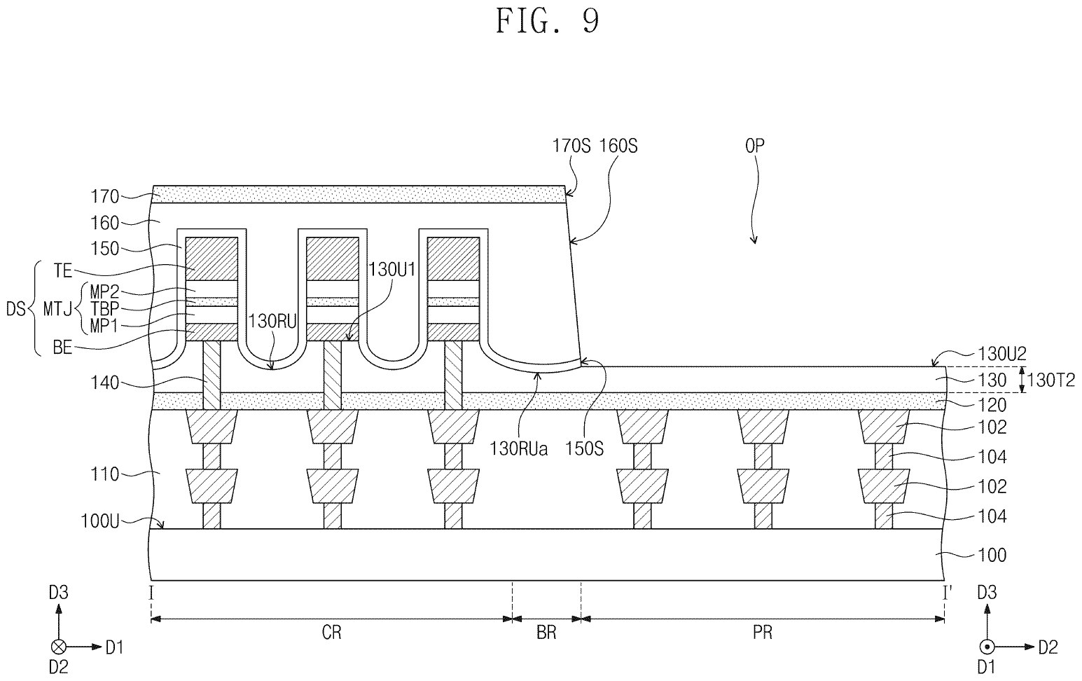

Referring to FIGS. 2 and 9, a peripheral opening OP may be formed on the peripheral region PR and may expose the upper surface 130U2 of the second lower insulating layer 130 on the peripheral region PR. The peripheral opening OP may expose a side surface 170S of the upper insulating layer 170, a side surface 160S of the cell insulating layer 160, and a side surface 150S of the capping insulating layer 150 on the boundary region BR.

Forming the peripheral opening OP may include performing a second etching process to remove the upper insulating layer 170, the cell insulating layer 160, and the capping insulating layer 150 on the peripheral region PR. For example, forming the peripheral opening OP may include forming a cell mask pattern on the upper insulating layer 170 on the cell region CR, and performing the second etching process using the cell mask pattern as an etch mask. For example, the cell mask pattern may be a photo resist pattern. As the upper insulating layer 170, the cell insulating layer 160, and the capping insulating layer 150 on the peripheral region PR are removed by the second etching process, the upper surface 130U of the second insulating layer 170 on the peripheral region PR may be exposed, and the side surface 170S of the upper insulating layer 170, the side surface 160S of the cell insulating layer 160, and the side surface 150S of the capping insulating layer 150 may be exposed.

When the second lower insulating layer 130 on the peripheral region PR is over-etched during the second etching process, the first lower insulating layer 120 on the peripheral region PR may be recessed by the second etching process, and in addition, upper surfaces of the uppermost wiring lines 102 on the peripheral region PR may be recessed by the second etching process. Accordingly, defects may occur in the uppermost wiring lines 102.

According to various example embodiments, however, the second lower insulating layer 130 on the peripheral region PR may be controlled to have a required or expected thickness 132T using the blocking mask pattern BM. Accordingly, the first lower insulating layer 120 and the uppermost wiring lines 102 on the peripheral region PR may be prevented from or reduced in likelihood of being recessed by the second etching process.

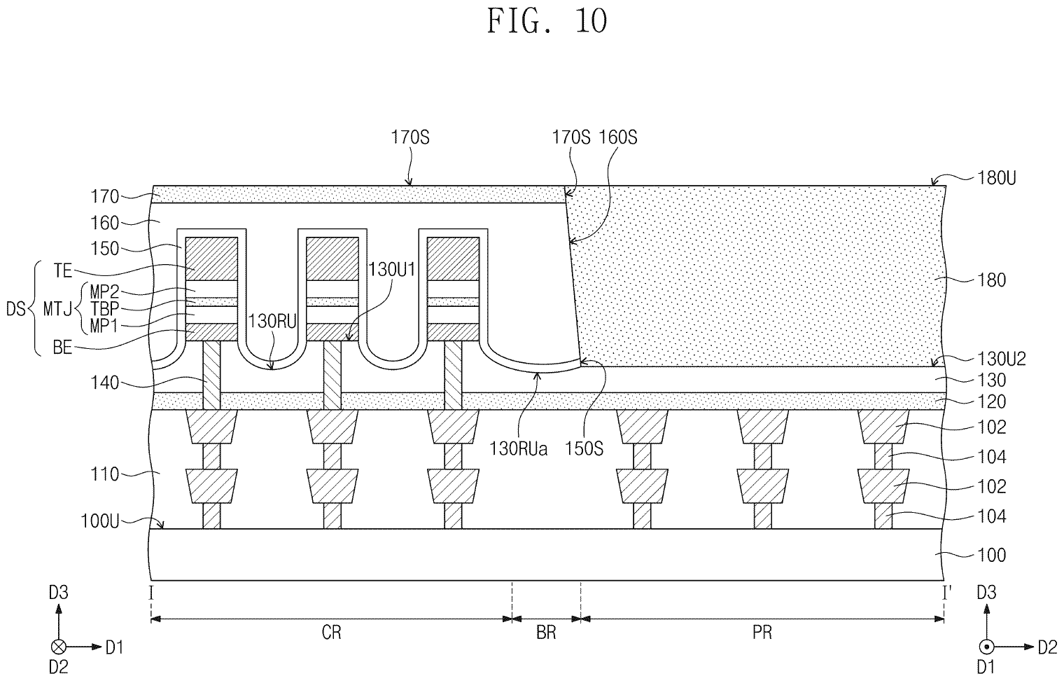

Referring to FIGS. 2 and 10, a peripheral insulating layer 180 may be formed to fill the peripheral opening OP. The peripheral insulating layer 180 may be in contact with the upper surface 130U of the second lower insulating layer 130 on the peripheral region PR, and may be in contact with the side surface 150S of the capping insulating layer 150, the side surface 160S of the cell insulating layer 160, and the side surface 170S of the upper insulating layer 170 on the boundary region BR. Forming the peripheral insulating layer 180 may include, for example, forming an insulating layer that fills the peripheral opening OP, and planarizing the insulating layer until an upper surface of the upper insulating layer 170 is exposed. The insulating layer may be formed using, for example, a chemical vapor deposition process. The planarizing process may be performed using, for example, at least one of an etch-back process and a chemical mechanical polishing process.

Referring to FIGS. 2 and 11, first cell trenches 192T may be formed on the cell region CR. The first cell trenches 192T may be spaced apart from each other in the first direction D1 and may extend in the second direction D2. Each of the first cell trenches 192T may have a line shape extending in the second direction D2, and may expose corresponding data storage patterns DS spaced apart from each other in the second direction D2 among the data storage patterns DS. Each of the first cell trenches 192T may penetrate the upper insulating layer 170 and an upper portion of the cell insulating layer 160. Each of the first cell trenches 192T may expose the upper electrode TE of each of the corresponding data storage patterns DS.

Peripheral trenches 210T may be formed on the peripheral region PR and in the peripheral insulating layer 180. Each of the peripheral trenches 210T may penetrate an upper portion of the peripheral insulating layer 180. Peripheral holes 220H may extend from bottom surfaces of the peripheral trenches 210T toward the substrate 100. Each of the peripheral holes 220H may penetrate a lower portion of the peripheral insulating layer 180, and may penetrate the second lower insulating layer 130 and the first lower insulating layer 120 on the peripheral region PR. Each of the peripheral holes 220H may expose an upper surface of the corresponding wiring line 102 among the uppermost wiring lines 102.

Referring to FIG. 12, each of the peripheral holes 220H may include a first region 220H1 in the first lower insulating layer 120, a second region 220H2 in the second lower insulating layer 130, and a third region 220H3 in the peripheral insulating layer 180. Each of the peripheral holes 220H may have a width in a direction parallel to the upper surface 100U of the substrate 100. A first width W1 of the first region 220H1 may be smaller than a third width W3 of the third region 220H3, and a second width W2 of the second region 220H2 may decrease as the second region 220H2 is farther away from the third region 220H3 in a direction perpendicular to the upper surface 100U of the substrate 100 and is closer to the first region 220H1. An inner surface of the first region 220H1 may be inclined at a first angle θ1 with respect to a lower surface 120L of the first lower insulating layer 120, and an inner surface of the second region 220H2 may be inclined at a second angle θ2 with respect to a lower surface 130L of the second lower insulating layer 130. The second angle θ2 may be different from the first angle θ1. An inner surface of the third region 220H3 may be inclined at a third angle θ3 with respect to the upper surface 130U2 of the second lower insulating layer 130 on the peripheral region PR. The second angle θ2 may be different from the third angle θ3. As an example, each of the first angle θ1 and the third angle θ3 may be less than or equal to 90°, and the second angle θ2 may be smaller than the first angle θ1 and the third angle θ3.

The second lower insulating layer 130 may include a material different from the first lower insulating layer 120 and the peripheral insulating layer 180, and accordingly, during the etching process to form the peripheral holes 220H, an etch rate of the second lower insulating layer 130 may be different from an etch rate of the first lower insulating layer 120 and the peripheral insulating layer 180. Accordingly, the width W2 of each of the second regions 220H2 of the peripheral holes 220H may decrease as the second regions 220H2 is farther away from the third region 220H3 and as the second regions 220H2 is closer to the first region 220H1. In addition, a slope of the inner surface of the second region 220H2 may be different from a slope of the inner surface of the first region 220H1 and a slope of the inner surface of the third region 220H3.

Referring again to FIGS. 2 and 3, first cell conductive lines 192 may be formed in the cell trenches 192T, respectively. Peripheral conductive lines 210 may be formed in each of the peripheral trenches 210T, and peripheral conductive contacts 220 may be formed in each of the peripheral holes 220H. Forming the first cell conductive lines 192, the peripheral conductive lines 210, and the peripheral conductive contacts 220 may include, for example, forming a conductive layer to fill the cell trenches 192T, the peripheral trenches 210T, and the peripheral holes 220H on the upper insulating layer 170 and the peripheral insulating layer 180, and planarizing the conductive layer until an upper surface 170U of the upper insulating layer 170 and an upper surface 180U of the peripheral insulating layer 180 are exposed. Through the planarization process, the upper surfaces 192U of the first cell conductive lines 192, the upper surface 170U of the upper insulating layer 170, the upper surface 180U of the peripheral insulating layer 180, and the upper surfaces 210U of the peripheral conductive lines 210 may be positioned at the same height as each other.

An upper interlayer insulating layer 200 may be formed on the cell region CR, the boundary region BR, and the peripheral region PR, and may cover the upper surface 170U of the upper insulating layer 170, the upper surfaces 192U of the conductive lines 192, the upper surface 180U of the peripheral insulating layer 180, and the upper surfaces 210U of the peripheral conductive lines 210.

Second cell conductive lines 196 and conductive contacts 194 may be formed in the upper interlayer insulating layer 200. Forming the second cell conductive lines 196 and the conductive contacts 194 may include, for example, forming second cell trenches penetrating an upper portion of the upper interlayer insulating layer 200, forming contact holes penetrating a lower portion of the upper interlayer insulating layer 200 from a bottom surface of each of the second cell trenches, forming a conductive layer to fill the second cell trenches and the contact holes on the upper interlayer insulating layer 200, and planarizing the conductive layer until an upper surface of the upper interlayer insulating layer 200 is exposed.

According to various example embodiments, on the peripheral region, the second lower insulating layer may be interposed between the first lower insulating layer and the peripheral insulating layer and may have the required thickness. Accordingly, during the etching process performed before the forming of the peripheral insulating layer, the first lower insulating layer and the wiring lines of the uppermost layer under the first lower insulating layer may be prevented from or reduced in likelihood of being recessed. Alternatively or additionally, the increase in the parasitic capacitance between the peripheral conductive contacts and/or the peripheral conductive lines may be suppressed, and the decrease in the resistance of the peripheral conductive contacts may be suppressed.

Accordingly, the semiconductor device capable of minimizing or reducing the defects during the manufacturing process and having the improved electrical characteristics, and the method manufacturing of the same may be provided.

While various example embodiments are described above, a person of ordinary skill in the art may understand that many modifications and variations are made without departing from the spirit and scope of the inventive concept defined in the following claims. Accordingly, example embodiments should be considered in all respects as illustrative and not restrictive, with the spirit and scope of the inventive concept being indicated by the appended claims. Additionally, example embodiments are not necessarily mutually exclusive with one another. For example, some example embodiments may include one or more features described with reference to one or more figures, and may also include one or more other features described with reference to one or more other figures.

What is claimed is:

1. A semiconductor device comprising:
a substrate including a cell region and a peripheral region;
a first lower insulating layer on the cell region and extending onto the peripheral region;
a second lower insulating layer on the cell region and on the first lower insulating layer and extending onto the first lower insulating layer on the peripheral region;
data storage patterns on the second lower insulating layer on the cell region;
a cell insulating layer on the cell region and on the second lower insulating layer and covering the data storage patterns; and
a peripheral insulating layer on the peripheral region and on the second lower insulating layer and including a material different from materials of the cell insulating layer,
wherein a thickness of the second lower insulating layer on the peripheral region is smaller than a maximum thickness of the second lower insulating layer on the cell region.

2. The semiconductor device of claim 1, wherein an upper surface of the second lower insulating layer on the peripheral region is at a lower height than an uppermost surface of the second lower insulating layer on the cell region.

3. The semiconductor device of claim 2, wherein
the second lower insulating layer on the cell region has a recessed upper surface that is recessed toward the substrate and is between the data storage patterns, and
the recessed upper surface of the second lower insulating layer on the cell region is at a lower height than the uppermost surface of the second lower insulating layer on the cell region.

4. The semiconductor device of claim 3, further comprising:
lower electrode contacts on the cell region and in the second lower insulating layer and respectively connected to the data storage patterns,
wherein the data storage patterns are on the lower electrode contacts, respectively, and
wherein the uppermost surface of the second lower insulating layer on the cell region is at a same height as upper surfaces of the lower electrode contacts.

5. The semiconductor device of claim 2, wherein the peripheral insulating layer is in contact with the upper surface of the second lower insulating layer on the peripheral region.

6. The semiconductor device of claim 5, wherein the peripheral insulating layer includes an insulating material having a lower dielectric constant than that of the cell insulating layer.

7. The semiconductor device of claim 5, further comprising:
an upper insulating layer on the cell insulating layer,
wherein the peripheral insulating layer is in contact with a side surface of the cell insulating layer and a side surface of the upper insulating layer.

8. The semiconductor device of claim 7, wherein the peripheral insulating layer includes an insulating material having a lower dielectric constant than that of the cell insulating layer and the upper insulating layer.

9. The semiconductor device of claim 1, wherein the second lower insulating layer includes a material different from materials of the first lower insulating layer.

10. The semiconductor device of claim 1, further comprising:
a peripheral conductive contact on the peripheral region, penetrating the first lower insulating layer and the second lower insulating layer and penetrating a lower portion of the peripheral insulating layer,
wherein the peripheral conductive contact includes a first portion in the first lower insulating layer, a second portion in the second lower insulating layer, and a third portion in the peripheral insulating layer, and
a width of the first portion is smaller than a width of the third portion.

11. The semiconductor device of claim 10, wherein a width of the second portion decreases as the second portion approaches the first portion.

12. The semiconductor device of claim 10, further comprising:
lower electrode contacts on the cell region, penetrating the first lower insulating layer and the second lower insulating layer, and connected to the data storage patterns, respectively; and
wiring lines between the substrate and the first lower insulating layer,
wherein the lower electrode contacts and the peripheral conductive contact penetrate the first lower insulating layer and are connected to the wiring lines.

13. A semiconductor device comprising:
a substrate including a cell region and a peripheral region;
a first lower insulating layer on the cell region and extending onto the peripheral region;
a second lower insulating layer on the cell region and on the first lower insulating layer and extending onto the first lower insulating layer on the peripheral region;
data storage patterns on the second lower insulating layer on the cell region;
lower electrode contacts on the cell region, penetrating the first lower insulating layer and the second lower insulating layer, and connected to the data storage patterns, respectively;
a cell insulating layer on the second lower insulating layer on the cell region and covering the data storage patterns;
a peripheral insulating layer on the peripheral region and on the second lower insulating layer and including a material different from materials of the cell insulating layer; and
a peripheral conductive contact in the peripheral insulating layer and penetrating the first lower insulating layer and the second lower insulating layer on the peripheral region,
wherein an upper surface of the second lower insulating layer on the peripheral region is at a lower height than an uppermost surface of the second lower insulating layer on the cell region, and
the peripheral insulating layer is in contact with a side surface of the cell insulating layer and the upper surface of the second lower insulating layer on the peripheral region.

14. The semiconductor device of claim 13, wherein
The second lower insulating layer on the cell region has a recessed upper surface that is recessed toward the substrate and is between the data storage patterns, and
the recessed upper surface of the second lower insulating layer on the cell region is at a lower height than the uppermost surface of the second lower insulating layer on the cell region.

15. The semiconductor device of claim 14, further comprising:
a capping insulating layer interposed between a side surface of each of the data storage patterns and the cell insulating layer, and extending between the recessed upper surface of the second lower insulating layer on the cell region and the cell insulating layer,
wherein the peripheral insulating layer is in contact with a side surface of the capping insulating layer.

16. The semiconductor device of claim 15, further comprising:
an upper insulating layer on the cell insulating layer,
wherein the peripheral insulating layer is in contact with a side surface of the upper insulating layer.

17. The semiconductor device of claim 13, wherein the peripheral insulating layer includes an insulating material having a lower dielectric constant than that of the cell insulating layer.

18. The semiconductor device of claim 13, wherein the first lower insulating layer and the second lower insulating layer include different materials.

19. The semiconductor device of claim 18, wherein
the peripheral conductive contact includes a first portion in the first lower insulating layer, a second portion in the second lower insulating layer, and a third portion in the peripheral insulating layer,
a side surface of the first portion is inclined at a first angle with respect to a lower surface of the first lower insulating layer,
a side surface of the second portion is inclined at a second angle with respect to a lower surface of the second lower insulating layer, and
the second angle is different from the first angle.

20. The semiconductor device of claim 19, wherein
a side surface of the third portion is inclined at a third angle with respect to the upper surface of the second lower insulating layer on the peripheral region, and
the second angle is different from the third angle.
